(19) United States
(12) Patent Application Publication
(10) Pub. No.: US 2026/0015708 A1
(43) Pub. Date: Jan. 15, 2026

(54) MASK ASSEMBLY AND METHOD OF MANUFACTURING MASK ASSEMBLY

(71) Applicant: Samsung Display Co., LTD., Yongin-si (KR)

(72) Inventors: MIN JI JANG, Yongin-si (KR); JONG DAE LEE, Yongin-si (KR)

(21) Appl. No.: 19/010,917

(22) Filed: Jan. 6, 2025

(30) Foreign Application Priority Data
Jul. 10, 2024 (KR) 10-2024-0090984

(51) Int. Cl. C23C 14/04; H10K 71/16

(52) U.S. Cl. CPC C23C 14/042; H10K 71/166

(57) ABSTRACT

A mask assembly may include a frame, a mask sheet, and an auxiliary stick. The mask sheet may include a sheet frame and a protrusion protruding from the sheet frame. The sheet frame may have inner surfaces defining an opening of the sheet frame, and the protrusion may protrude toward the opening in a second direction that intersects a first direction, from one of the inner surfaces of the sheet frame extending in the first direction. The mask sheet may include a stick seating groove extending in the second direction from the protrusion to the sheet frame. The auxiliary stick may be disposed within the stick seating groove. The auxiliary stick may be provided in plurality, and the plurality of auxiliary sticks may be arranged such that the plurality of auxiliary sticks are spaced apart from each other in the second direction.

This application claims priority to Korean Patent Application No. 10-2024-0090984, filed on Jul. 10, 2024, and all the benefits accruing therefrom under 35 U.S.C. § 119, the content of which in its entirety is herein incorporated by reference.

### BACKGROUND

### 1. Technical Field

The present disclosure relates to a mask assembly and a method of manufacturing the mask assembly, and more specifically, to a mask assembly with improved deposition precision and reliability, as well as a method of manufacturing the mask assembly.

### 2. Description of the Related Art

Displays can be manufactured through various processes, and a deposition process may be employed in the manufacturing process. In a deposition process for manufacturing a display, a mask assembly that is closely adhered to a substrate may be used.

The mask assembly may be utilized in the deposition process to form a pattern on the substrate and includes an opening that defines the deposition area on the substrate.

The mask assembly may be fabricated with a small thickness to prevent shadowing, and accordingly, there have been studies for improving the deposition precision and reliability of the mask assembly.

### SUMMARY

The present disclosure provides a mask assembly with improved deposition precision and reliability for a deposition process.

The present disclosure also provides a method of manufacturing a mask assembly with improved deposition precision and reliability for a deposition process.

A mask assembly in accordance with an embodiment of the present disclosure may include a frame, a mask sheet, and an auxiliary stick. The mask sheet may include a sheet frame coupled to the frame and a protrusion protruding from the sheet frame. The sheet frame may include inner surfaces defining an opening of the sheet frame. The protrusion may protrude toward the opening in a second direction that intersects a first direction, from one of the inner surfaces of the sheet frame extending in the first direction.

The mask sheet may be provided with a stick seating groove extending in the second direction from the protrusion to the sheet frame.

The auxiliary stick may be coupled to the mask sheet and disposed within the stick seating groove.

According to an embodiment of the present disclosure, the sheet frame and the protrusion may have an integrated shape.

According to an embodiment of the present disclosure, the auxiliary stick may be provided in plurality, and the plurality of auxiliary sticks may be arranged such that the plurality of auxiliary sticks are spaced apart from each other in the second direction.

According to an embodiment of the present disclosure, a height of the auxiliary stick in a third direction, which intersects the first direction and the second direction, may be smaller than or equal to a depth of the stick seating groove in the third direction.

According to an embodiment of the present disclosure, a thickness of the sheet frame and a thickness of the protrusion may be equal in the third direction.

According to an embodiment of the present disclosure, a length of the stick seating groove in the second direction may be smaller than a length from an end of the protrusion adjacent to the opening in the second direction to an outer surface of the sheet frame facing the end of the protrusion.

According to an embodiment of the present disclosure, in a plan view, the auxiliary stick may overlap with the protrusion and the sheet frame, and a length of the auxiliary stick in the second direction may be smaller than or equal to a length of the stick seating groove in the second direction.

According to an embodiment of the present disclosure, an end of the auxiliary stick facing the opening in the second direction may be spaced apart from the end of the protrusion in the second direction, and another end of the auxiliary stick may be spaced apart from the outer surface of the sheet frame facing opposite to the end of the protrusion.

According to an embodiment of the present disclosure, the mask sheet may include a first surface adjacent to a target substrate and a second surface facing opposite to the first surface, and the stick seating groove may be provided on the first surface of the mask sheet.

According to an embodiment of the present disclosure, the sheet frame and the auxiliary stick may include Invar 36.

According to an embodiment of the present disclosure, a bottom surface of the auxiliary stick may be inclined at a predetermined angle relative to a bottom surface of the stick seating groove.

According to an embodiment of the present disclosure, the predetermined angle may be 5° or greater.

According to an embodiment of the present disclosure, the stick seating groove may be provided in plurality, and the auxiliary stick may have an H-beam shape extending in the second direction.

According to an embodiment of the present disclosure, the protrusion may include: a first area overlapping with the auxiliary stick on a plane perpendicular to the second direction and having a width equal to a width of the auxiliary stick in the first direction; and a second area not overlapping with the first area, where the second area has a width equal to the width of the first area on the plane and has an area equal to the first area.

A second moment of area of the first area relative to the first direction may be greater than or equal to a second moment of area of the second area relative to the first direction.

A method for manufacturing a mask assembly according to an embodiment of the present disclosure may include: providing a mask sheet including a sheet frame having inner surfaces defining an opening of the sheet frame, and a protrusion protruding toward the opening in a second direction that intersects a first direction, from one of the inner surfaces of the sheet frame extending in the first direction; forming a stick seating groove on the mask sheet, the stick seating groove extending in the second direction from the protrusion to the sheet frame; and disposing an auxiliary stick within the stick seating groove.

According to an embodiment of the present disclosure, disposing the auxiliary stick may include: aligning, on the protrusion, a center axis of an original stick extending in the second direction with a center axis of the stick seating groove extending in the second direction; stretching the original stick in the second direction; and welding the stretched original stick to the stick seating groove.

According to an embodiment of the present disclosure, forming the stick seating groove may include forming the stick seating groove on a first surface of the mask sheet.

Welding the stretched original stick is performed upward from a second surface to the first surface, and the second surface faces opposite to the first surface of the mask sheet where the stick seating groove is formed.

According to an embodiment of the present disclosure, the method for manufacturing a mask assembly may further include removing a portion of the stretched original stick that does not overlap with the stick seating groove in a plan view.

The mask assembly in accordance with an embodiment of the present disclosure may include a frame, a mask sheet coupled to the frame, and an auxiliary stick coupled to the mask sheet.

The mask sheet may include a first rib, a second rib, a connecting portion and a protrusion.

The first rib may extend in a first direction, and the second rib may extend in the first direction and may be spaced apart from the first rib in the first direction. The connecting portion may be connected to the first rib and the second rib. The protrusion may be connected between the first rib and the second rib in the first direction, may protrude in a second direction intersecting the first direction relative to the first rib and the second rib, and may include a stick seating groove extending in the first direction. The auxiliary stick may be disposed within the stick seating groove.

According to an embodiment of the present disclosure, the first rib, the second rib, the connecting portion and the protrusion may have an integrated shape, and respective thicknesses of the first rib, the second rib, the connecting portion and the protrusion may be equal to one another.

According to an embodiment of the present disclosure, the auxiliary stick included in the mask sheet may alleviate deflection of the protrusion, thereby providing a mask assembly with improved deposition precision and reliability as well as a method of manufacturing such a mask assembly.

### BRIEF DESCRIPTION OF THE DRAWINGS

These and/or other features will become apparent and more readily appreciated from the following description of the embodiments, taken in conjunction with the accompanying drawings in which:

FIG. 1 is an exploded perspective view of a mask assembly in accordance with an embodiment of the present disclosure;

FIG. 2 is a perspective view of the mask assembly in accordance with an embodiment of the present disclosure;

FIG. 3 is a cross-sectional view of a deposition apparatus in accordance with an embodiment of the present disclosure;

FIG. 4 is a plan view illustrating a mask sheet in accordance with an embodiment of the present disclosure;

FIG. 5 is a magnified view of the AA region illustrated in FIG. 4;

FIG. 6 is a cross-sectional view taken along the A-A′ line of FIG. 4;

FIG. 7 is a cross-sectional view of the protrusion in accordance with an embodiment of the present disclosure;

FIG. 8 is a cross-sectional view taken along the B-B′ line of FIG. 5;

FIG. 9 is a partial perspective view of the protrusion and the sheet frame in accordance with an embodiment of the present disclosure;

FIG. 10 is a cross-sectional view taken along the C-C′ line of FIG. 9;

FIG. 11 is a partial cross-sectional view of the protrusion and the sheet frame in accordance with an embodiment of the present disclosure;

FIG. 12 is a partial cross-sectional view of the protrusion in accordance with an embodiment of the present disclosure;

FIG. 13 is a cross-sectional view taken along the D-D′ line of FIG. 12;

FIGS. 14A to 14F are perspective views illustrating a method of manufacturing a mask assembly in accordance with an embodiment of the present disclosure; and

FIGS. 15A to 15D are cross-sectional views illustrating how the auxiliary stick is disposed in accordance with an embodiment of the present disclosure.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are described herein, by referring to the figures, to explain features of the present disclosure.

When an element is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. In some aspects, if one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, and the like illustrated in the drawings.

Terms such as “first” and “second” may be used in describing various elements, but the above elements shall not be restricted to the above terms. The above terms may be used to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

Moreover, relative terms, such as “below,” “under,” “beneath,” “lower,” “bottom,” “above,” “over,” “upper,” “top,” and the like, may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The example term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The example terms “below” or “beneath” can therefore encompass an orientation of both above and below.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

In the present specification, if any embodiment can be differently implemented, the specified order of process may be performed differently than the described order. For example, two processes described to be performed sequentially may be performed simultaneously or performed in a reverse order.

Hereinafter, certain embodiments of a mask assembly in accordance with the present disclosure will be described in detail with reference to the accompanying drawings. In describing the embodiments of the present disclosure with reference to the accompanying drawings, any identical or corresponding elements will be given same reference numerals and will not be redundantly described.

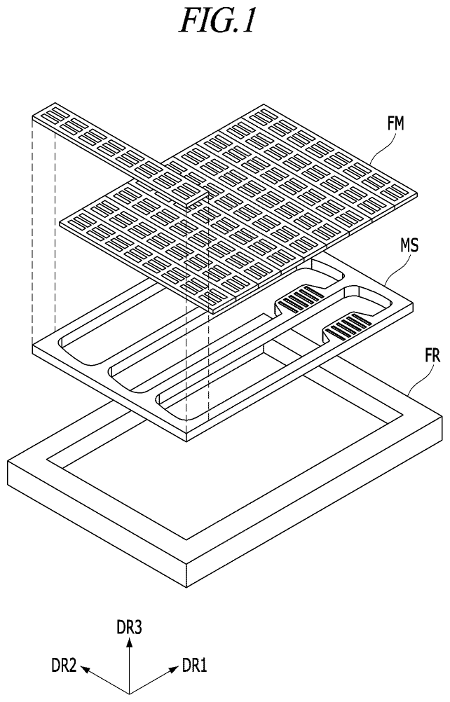

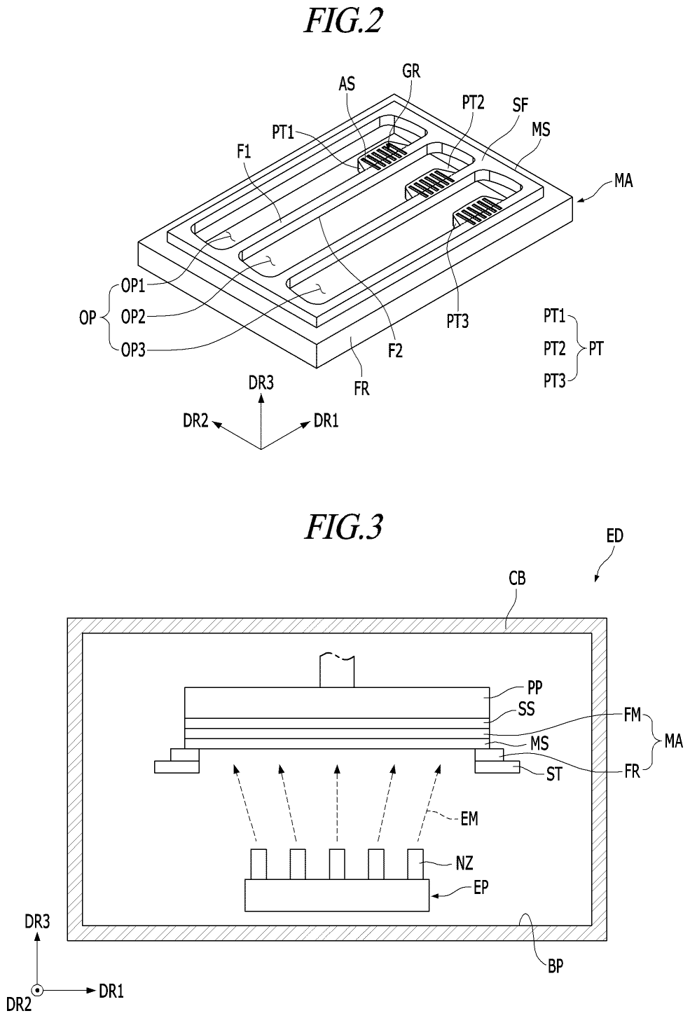

FIG. 1 is an exploded perspective view of a mask assembly in accordance with an embodiment of the present disclosure. FIG. 2 is a perspective view of the mask assembly in accordance with an embodiment of the present disclosure. FIG. 3 is a cross-sectional view of a deposition apparatus in accordance with an embodiment of the present disclosure.

Referring to FIGS. 1 to 3, the mask assembly MA may include a mask sheet MS, a frame FR, and an auxiliary stick AS. The mask assembly MA is an open mask used in a deposition process and may have a shape corresponding to a cell unit pattern of a deposition target substrate. In an embodiment of the present disclosure, the mask assembly MA may additionally include an additional mask FM on the mask sheet MS that corresponds to a pixel pattern. The additional mask FM may have a shape corresponding to a pixel unit pattern of the deposition target substrate. However, the configuration in the present embodiment of the disclosure is not limited thereto, and the mask sheet MS may be directly faced to the deposition target substrate to proceed with the deposition process.

The mask sheet MS may include a sheet frame SF, protrusions PT, and stick seating grooves GR. The mask sheet MS may be provided with an opening OP defining a cell-unit deposition area. The mask sheet MS may be disposed on the frame FR, and the frame FR may be disposed on a stage ST of a deposition equipment to secure the mask assembly MA to the deposition equipment.

The sheet frame SF may be disposed on and directly coupled to the frame FR. In an embodiment, the sheet frame SF may have coupling grooves (not illustrated) defined for coupling with the frame FR.

The sheet frame SF may define openings OP corresponding to a single cell area formed on the deposition target substrate together with the protrusions PT. Moreover, the sheet frame SF may be coupled with the protrusions PT and, together with the protrusions PT, have a shape surrounding the openings OP.

The protrusions PT may extend from an inner surface of the sheet frame SF extending in a first direction DR1 and may protrude in a second direction DR2.

The stick seating grooves GR may be disposed within the mask sheet MS. For example, embodiments of the present disclosure include forming the stick seating grooves GR within the mask sheet MS. The stick seating grooves GR may extend in the second direction DR2 from the protrusions PT to the sheet frame SF. The stick seating grooves GR may provide a space configured to accommodate the auxiliary sticks AS, which will be described later.

The frame FR may have the mask sheet MS coupled thereto and provide a frame for having the mask assembly MA mounted on a deposition apparatus ED. The mask sheet MS may be stretched in four directions to prevent the mask sheet MS from sagging and then coupled to the frame FR. The four directions may be a first direction DR1, a direction opposite to the first direction DR1, a second direction DR2 and a direction opposite to the second direction DR2. The frame FR may be formed of a material with little deformation (e.g., a material having a relative high tolerance to deformation), for example, a high-rigidity metal.

The auxiliary sticks AS may be coupled with the mask sheet MS and disposed within the stick seating grooves GR.

The mask sheet MS, the frame FR and the auxiliary sticks AS will be further described later in greater detail.

Referring to FIG. 3, the deposition apparatus ED according to an embodiment may include a chamber CB, a deposition source EP, a stage ST, a mask assembly MA and a fixing member PP.

The chamber CB may provide an internal space in which the deposition process is performed. The internal space of the chamber CB may be arranged with the deposition source EP, the stage ST, the mask assembly MA, the additional mask FM and the fixing member PP. The chamber CB may provide a sealed space, and the interior of the chamber CB may be in a vacuum state. The chamber CB may be equipped with at least one gate (not illustrated), and the chamber CB may be opened and closed through the gate not illustrated. The mask assembly MA, the additional mask FM and a substrate SS may enter and exit through the gate (not illustrated).

The chamber CB may include a bottom surface BP, a ceiling surface (not illustrated) facing the bottom surface BP and side walls (not illustrated). The bottom surface BP of the chamber CB may be parallel to a plane where the first direction DR1 and the second direction DR2 intersect, and the normal direction of the bottom surface BP may be parallel to a third direction DR3.

The fixing member PP may be arranged on the ceiling surface (not illustrated) of the chamber CB and may face the deposition source EP in the third direction DR3. The fixing member PP may be configured to make the substrate SS in close contact with the mask assembly MA. The fixing member PP may include magnetic materials for bringing the mask assembly MA and the substrate SS into close contact. For example, the magnetic materials may be configured to generate a magnetic force to fix the mask assembly MA, and the substrate SS placed between the mask assembly MA and the fixing member PP may be in close contact with the mask assembly MA. However, the present disclosure is not limited to the above-described configuration, and the fixing member PP may be a jig or a robot arm configured for holding the mask assembly MA.

The substrate SS may be interposed between the mask assembly MA and the fixing member PP. The substrate SS may be a workpiece onto which a deposition material is deposited. The substrate SS may include a support substrate and a synthetic resin layer disposed on the support substrate.

The deposition source EP may be disposed on the bottom surface BP of the chamber CB and may face the fixing member PP in the third direction DR3. The deposition source EP may include a storage space, in which a deposition material EM is accommodated, and at least one nozzle NZ. The deposition material EM may include an inorganic, metal, or organic material that can sublimate or vaporize. For example, the deposition material EM may include an organic light-emitting material for forming a light-emitting pattern. The sublimed or vaporized deposition material EM may be sprayed toward the substrate SS through the nozzle NZ. The deposition material EM may be patterned by passing through the openings OP of the mask assembly MA and deposited on the substrate SS.

The stage ST may be interposed between the deposition source EP and the fixing member PP. The stage ST may support a back surface of the frame FR and may be placed in the path of movement of the deposition material EM supplied from the deposition source EP to the substrate SS. The stage ST may include a stage aperture. The deposition material EM may be supplied to the mask assembly MA through the stage aperture. The stage ST may have coupling grooves defined at corners of stage ST which support fastening the stage ST to a coupling member. The stage ST may be fixed to the coupling member in a bolt-fastening fashion through the coupling grooves.

The mask assembly MA may be interposed between the stage ST and the substrate SS. The mask assembly MA may include the frame FR, the mask sheet MS and the auxiliary stick AS. The mask assembly MA may have a pattern corresponding to the deposition area of the substrate SS. In an embodiment, the mask assembly MA may further include the additional mask FM.

The frame FR may be disposed on the stage ST, i.e., interposed between the mask sheet MS and the stage ST. The frame FR may have the mask sheet MS coupled thereto and may support the mask sheet MS. In an embodiment, the frame FR may have the additional mask FM coupled thereto on the mask sheet MS.

The frame FR may include a top surface facing the mask sheet MS, a back surface facing the top surface and facing a seating surface of the stage ST, and side surfaces connecting the top surface and the back surface. The frame FR may be provided in the form of a rectangular frame. Accordingly, the frame FR may include a frame aperture that overlaps with the stage aperture. The deposition material EM may be supplied to the mask sheet MS through the frame aperture.

The frame FR may have a predetermined rigidity. For example, the frame FR may include a metal such as, for example, stainless steel (SUS), Invar, nickel (Ni), and/or cobalt (Co).

The mask sheet MS may be interposed between the substrate SS and the frame FR. The mask sheet MS may include the opening OP defining a cell-unit deposition area. The deposition material EM may be supplied to the substrate SS through the opening.

The mask sheet MS may be coupled to the frame FR. For example, the mask sheet MS may be coupled to the frame FR by a welding process. In such a case, an end and the other end of the mask sheet MS may be placed on the frame FR, and the welding process is performed on the end and the other end of the mask sheet MS, thereby coupling the mask sheet MS with the frame FR.

The auxiliary sticks AS may be coupled to the mask sheet MS and disposed within the stick seating grooves GR. The auxiliary sticks AS will be described later in greater detail.

In an embodiment, the additional mask FM may be interposed between the mask sheet MS and the substrate SS. The additional mask FM may include a pixel opening defining a pixel-unit deposition area. The additional mask FM may be coupled to the frame FR on the mask sheet MS, together with the mask sheet MS.

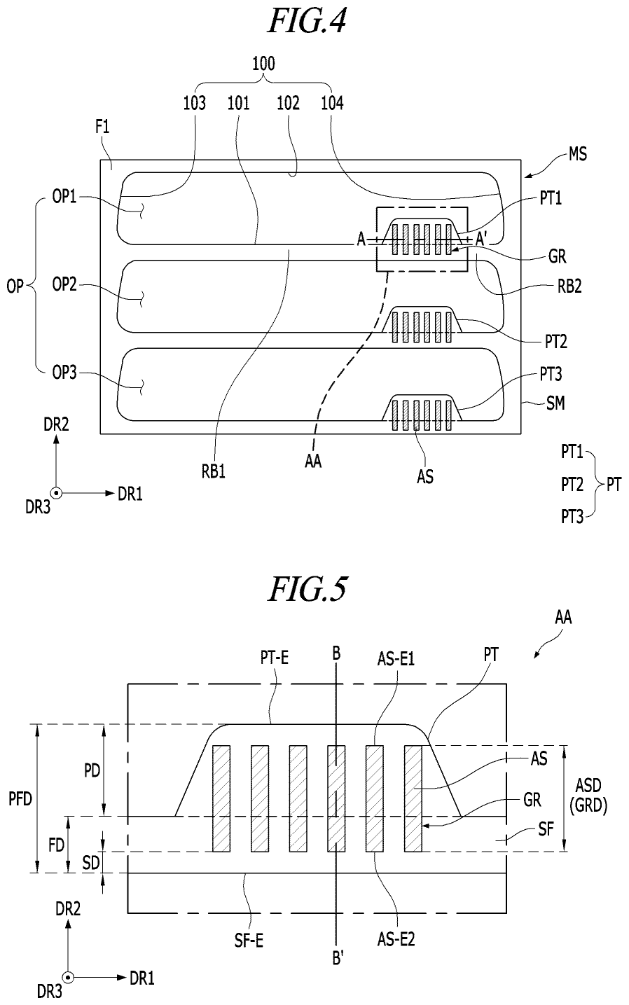

FIG. 4 is a plan view illustrating the mask sheet in accordance with an embodiment of the present disclosure. FIG. 5 is a magnified view of the AA region illustrated in FIG. 4.

Referring to FIG. 4, the mask sheet MS may include the sheet frame SF and the protrusions PT.

The mask sheet MS may be provided with openings OP. The openings OP may include a first opening OP1, a second opening OP2 and a third opening OP3. The openings OP may be regions defined by the sheet frame SF and the protrusions PT. The openings OP may have a shape surrounded by the sheet frame SF and the protrusions PT.

In an embodiment, the shape of the openings may be variously provided. The openings may not be limited to shapes such as, for example, triangles, squares, ellipses and circles but may have a shape corresponding to the deposition area of the target substrate.

The sheet frame SF may constitute an outer periphery of the mask sheet MS. In some aspects, the sheet frame SF may distinguish the openings OP. The sheet frame SF may include inner surfaces on which the protrusions PT extend and define the openings OP.

In an embodiment, the sheet frame SF may include a coupling part (not illustrated) coupled to the frame FR (see FIG. 2). For example, the coupling part (not illustrated) having a protruding shape may be arranged on an outer periphery of the sheet frame SF, and the frame FR may include a configuration corresponding to the protruding shape, such that the sheet frame SF and the frame FR may be stably coupled to each other.

Hereinafter, as all of the protrusions PT are identical or substantially identical to each other and all of the openings OP are also identical or substantially identical to each other, a first protrusion PT1 and the first opening OP1 will be mainly described, without describing other protrusions and openings redundantly. The term “substantially,” as used herein, means approximately or actually. The term “substantially identical” means approximately or actually identical. The term “substantially the same” means approximately or actually the same.

The sheet frame SF may include inner surfaces 100. The inner surfaces 100 may include a first inner surface 101, a second inner surface 102, a third inner surface 103 and a fourth inner surface 104. The first inner surface 101 and the second inner surface 102 may extend in the first direction DR1, and the third inner surface 103 and the fourth inner surface 104 may each be connected between the first inner surface 101 and the second inner surface 102 and may extend in the second direction DR2.

The first protrusion PT1 may extend from the first inner surface 101 extending in the first direction DR1 of the sheet frame SF and may protrude in the second direction DR2 toward the first opening OP1. Combined with the inner surfaces of the sheet frame SF, the first protrusion PT1 may form the first opening OP1. In the present embodiment, the first protrusion PT1 is illustrated and described as an example of being extended from the first inner surface 101.

In the present embodiment, the first protrusion PT1 and the inner surfaces 100 of the sheet frame SF may together have a shape surrounding the first opening OP1. However, the present embodiment is not limited to this configuration and shape. For example, the protrusion may extend from, among the inner surfaces 100 of the sheet frame SF, the third inner surface 103 or the fourth inner surface 104 extending in the second direction DR2 and protrude toward the first opening OP1 in the first direction DR1. That is, the protrusion may extend from one side of the inner surfaces 100 of the sheet frame SF surrounding the first opening OP1 and protrude toward the first opening OP1.

Although it is illustrated in FIG. 4 that the mask sheet MS includes the first to third protrusions PT1-PT3 and is provided with the first to third openings OP1-OP3, the embodiments of the present disclosure are not limited to the illustrated configuration. In an embodiment, for example, the mask sheet may include at least one protrusion and at least one opening.

The stick seating grooves GR may be disposed within the first protrusion PT1 and the sheet frame SF. The stick seating grooves GR may extend from the first protrusion PT1 to the sheet frame SF in the second direction DR2. The stick seating grooves GR may provide a space in which the auxiliary sticks AS, which will be described later, are disposed.

Referring to FIGS. 2 and 4, the mask sheet MS may include a first surface F1 adjacent to the frame FR and a second surface F2 facing the first surface F1. In an embodiment, the stick seating grooves GR may be provided on the second surface F2 of the mask sheet MS.

While it is illustrated in FIG. 4 that the stick seating grooves GR are provided in plurality, the embodiments of the present disclosure are not limited to the illustrated configuration, and at least one or more stick seating grooves GR may be provided.

In an embodiment, the stick seating groove may be provided in various shapes. For example, the stick seating groove may have an X or Y shape on a plane. Moreover, the stick seating grooves provided in plurality may have different lengths in the second direction DR2.

In an embodiment, the mask assembly MA may include a frame FR, a mask sheet MS, and an auxiliary stick AS coupled to the mask sheet MS. The mask sheet MS may include a first rib RB1, a second rib RB2, a connecting portion, and a protrusion PT provided with stick seating grooves extending in the first direction DR1. The first rib RB1 may extend in the first direction DR1, and the second rib (RB2) may be spaced apart from the first rib RB1 in the first direction DR1 and may extend in the first direction DR1. The first rib RB1 and the second rib RB2 may be connected by the connecting portion. The protrusion PT may be connected to the first rib RB1 and the second rib RB2 and may protrude in the second direction DR2 relative to the first rib RB1 and the second rib RB2. The auxiliary sticks AS may be disposed within the stick seating groove GR.

In an embodiment, the sheet frame SF and the protrusion PT may have an integrated shape. For example, the sheet frame SF and the protrusion PT may be integrally formed.

In an embodiment, the first rib RB1, the second rib RB2, the connecting portion, and the protrusion PT may have an integrated shape. For example, the first rib RB1, the second rib RB2, the connecting portion, and the protrusion PT may be integrally formed. The first rib RB1, the second rib RB2, the connecting portion, and the protrusion PT may have the same thickness. For example, respective thicknesses of the first rib RB1, the second rib RB2, the connecting portion, and the protrusion PT may be equal to one another.

Referring to FIG. 5, in an embodiment, the length GRD of the stick seating grooves GR in the second direction DR2 may be smaller than the length PFD from an end PT-E of the first protrusion PT1 adjacent to the first opening OP1 in the second direction DR2 to an outer surface SF-E of the sheet frame SF facing the end PT-E of the first protrusion PT1. That is, the length GRD of the stick seating grooves GR in the second direction DR2 may be smaller than the sum of the width FD of the sheet frame SF in the second direction DR2 and the width PD of the first protrusion PT1 in the second direction DR2. In some aspects, the stick seating grooves GR may be disposed to be spaced apart from each other by a predetermined distance SD from the end PT-E of the first protrusion PT1 and the outer surface SF-E of the sheet frame SF. Therefore, on the plane, the stick seating grooves GR may not come into contact with the inner surfaces 100 of the mask sheet MS, with no gap formed between the pattern of the mask sheet MS in close contact with the substrate during the deposition process, thereby enabling stable deposition on the substrate.

Referring to FIGS. 4 and 5, the auxiliary sticks AS may be disposed, respectively, within the stick seating grooves GR. The auxiliary sticks AS may be coupled, respectively, to the stick seating grooves GR in which the auxiliary sticks AS are respectively disposed. The auxiliary sticks AS may be coupled to the stick seating grooves GR provided in the mask sheet MS to mitigate the sagging of the protrusion PT.

In an embodiment, the auxiliary sticks AS may overlap with the first protrusion PT1 and the sheet frame SF in a plan view. That is, the auxiliary sticks AS may extend from the first protrusion PT1 to the sheet frame SF in the second direction DR2.

In an embodiment, the length ASD of the auxiliary sticks AS may be less than the length of the stick seating grooves GR. Therefore, the auxiliary sticks AS may be seated in the stick seating grooves GR.

In an embodiment, an end AS-E1 of the auxiliary sticks AS facing the first opening OP1 in the second direction DR2 may be spaced apart from the end PT-E of the first protrusion PT1, and the other end AS-E2 of the auxiliary sticks AS may be spaced apart from the outer surface SF-E of the sheet frame SF.

In an embodiment, the auxiliary sticks AS may include Invar 36.

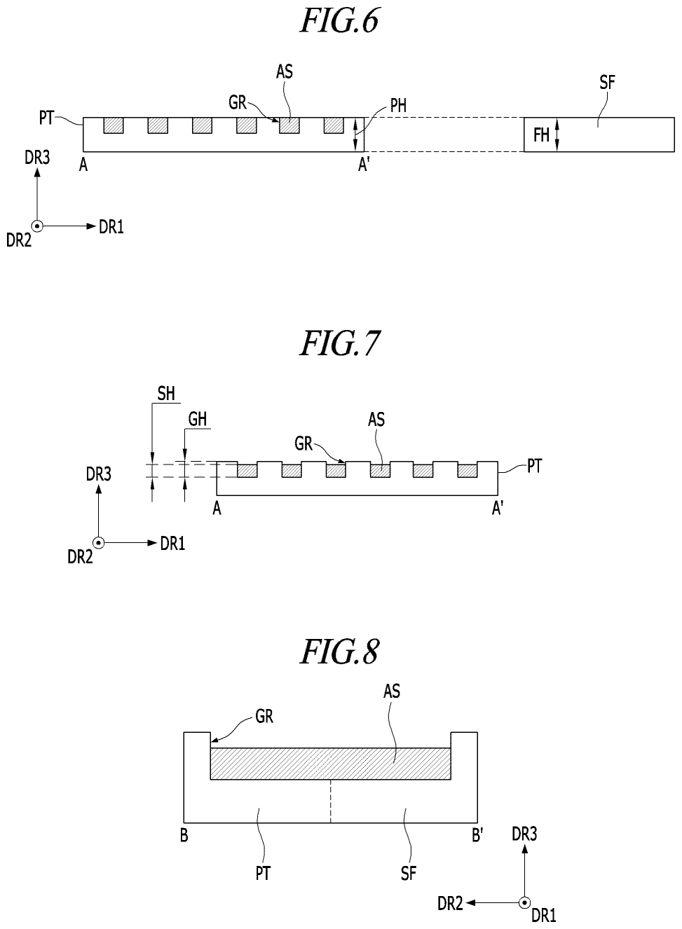

FIG. 6 is a cross-sectional view taken along the A-A′ line of FIG. 4. FIG. 7 is a cross-sectional view of the protrusion in accordance with an embodiment of the present disclosure. FIG. 8 is a cross-sectional view taken along the B-B′ line of FIG. 5.

Referring to FIG. 6, in an embodiment, the height PH of the first protrusion PT1 in the third direction DR3 may be equal to the height FH of the sheet frame SF in the third direction DR3. That is, the mask sheet MS may have a uniform thickness overall. Therefore, when the deposition process is performed, the top surface of the mask sheet MS may be uniformly adhered to the substrate.

Referring to FIGS. 7 and 8, in an embodiment, the height SH of the auxiliary sticks AS in the third direction DR3 may be less than the depth GH of the stick seating grooves GR in the third direction DR3. Therefore, the auxiliary sticks AS seated in the stick seating grooves GR may not protrude from the top surface of the mask sheet MS. In a comparative example, as the top surface of the auxiliary sticks protrudes over the top surface of the mask sheet, cracks may be caused in the substrate due to the auxiliary sticks in close contact with the substrate in the deposition process performed in a vacuum state.

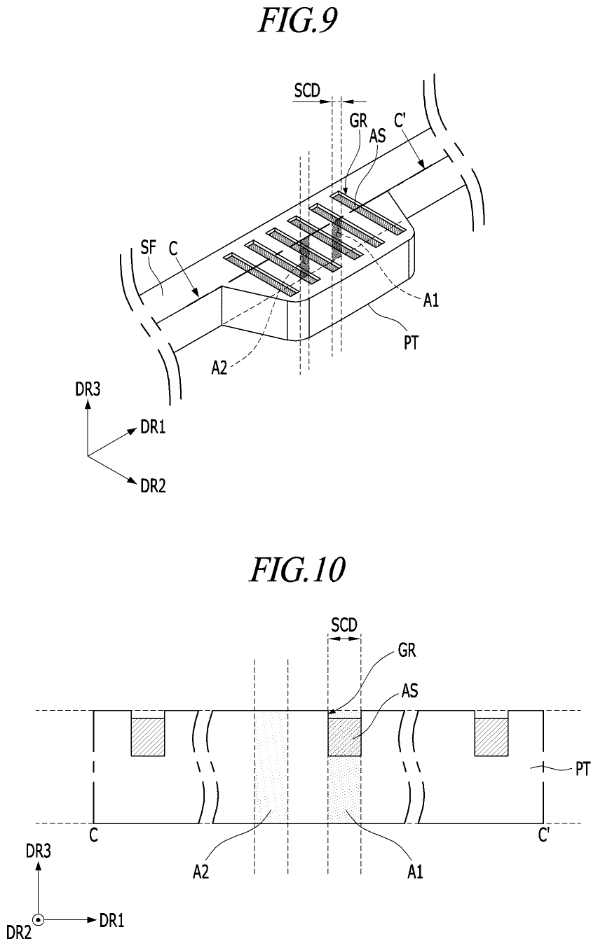

FIG. 9 is a partial perspective view of the protrusion and the sheet frame in accordance with an embodiment of the present disclosure. FIG. 10 is a cross-sectional view taken along the C-C′ line of FIG. 9.

Referring to FIGS. 9 and 10, the protrusion PT in accordance with an embodiment of the present disclosure may have a first area A1 and a second area A2 defined therein.

The first are A1 may overlap with the auxiliary stick AS on a plane perpendicular to the second direction DR2 and have a width equal to the width SCD of the auxiliary stick in the first direction DR1. On the aforementioned plane, the first are A1 may overlap with the auxiliary stick AS.

The second area A2 may not overlap with the first are A1 on the above-mentioned plane but may have the same width and area as the first area A1. On this plane, the first are A1 may be an area that overlaps with the auxiliary stick AS, and the second area A2 may be an area that has the same area as the first area A1 between adjacent auxiliary sticks AS.

In a comparative example, the mask assembly may not include auxiliary sticks, and the mask sheet may include protrusions. Even if the mask sheet is subjected to tensile forces in all four directions and attached to the frame, these forces may not be applied to the protrusions, or relatively less tensile forces may be applied, leading to sagging of the protrusions. If the protrusions sag, a gap may form between the substrate and the mask assembly, causing the deposition material to clump together in an icicle-like formation during the deposition process. In some aspects, as the protrusions sag, the sheet frame connected to the protrusions may experience a moment, leading to twisting.

In an embodiment of the present invention, the second moment of area of the first area A1 may be greater than or equal to the second moment of area of the second area A2. In other words, by having the auxiliary stick AS coupled to the stick seating groove GR, the sagging of the protrusion PT may be mitigated, thereby improving the deposition precision in the deposition. Furthermore, as the sagging of the protrusion PT is alleviated, the sheet frame is less deformed, which may improve the reliability of the mask assembly MA.

FIG. 11 is a partial cross-sectional view of the protrusion and the sheet frame in accordance with an embodiment of the present disclosure.

Referring to FIG. 11, in an embodiment, the bottom surface of the auxiliary stick AS may be inclined at a predetermined angle θ to the bottom surface of the stick seating groove GR. In some embodiments, the predetermined angle θ may be 5° or greater. Therefore, the second moment of area of the first area A1 may be increased, and the sagging of the protrusion PT may be mitigated.

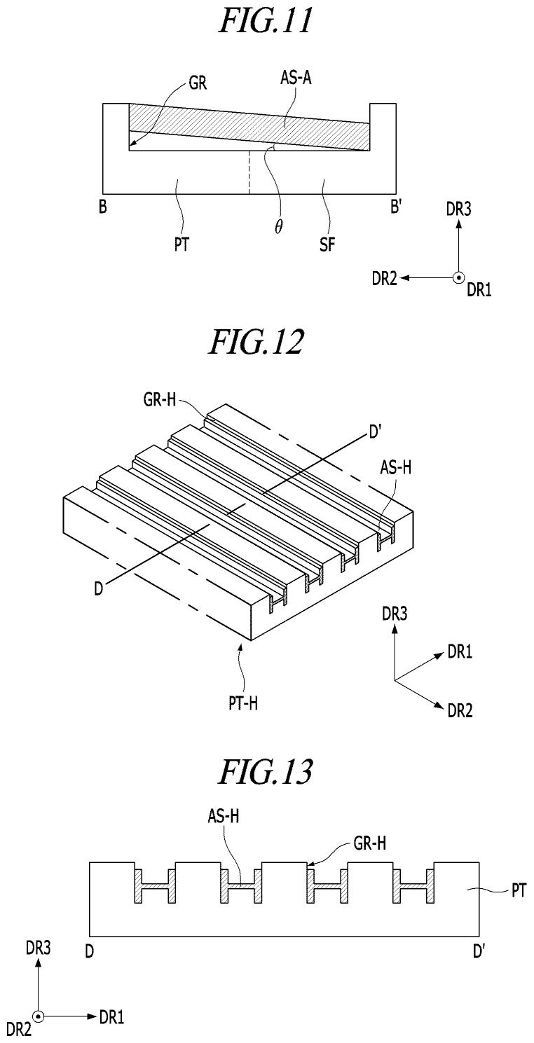

FIG. 12 is a partial cross-sectional view of the protrusion in accordance with an embodiment of the present disclosure. FIG. 13 is a cross-sectional view taken along the D-D′ line of FIG. 12. Referring to FIGS. 12 and 13, in an embodiment, auxiliary sticks AS-H may have an H-beam shape extending in the second direction DR2. As the auxiliary sticks AS-H have an H-beam shape, stick seating grooves GR-H may be shaped such that the stick seating grooves GR-H may accommodate the auxiliary sticks AS-H.

The H-beam shape may be designed to maximize the second moment of area about the extending center axis, providing an excellent bending rigidity. The H-beam shape of the auxiliary sticks AS-H may mitigate the sagging of the protrusions PT-H.

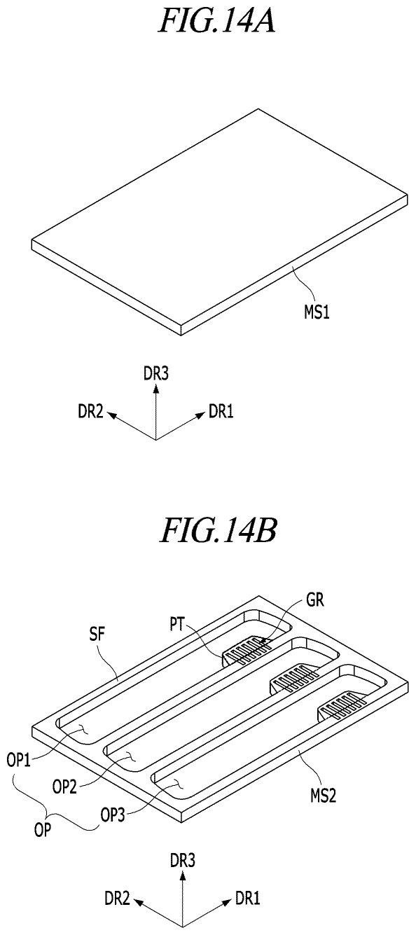

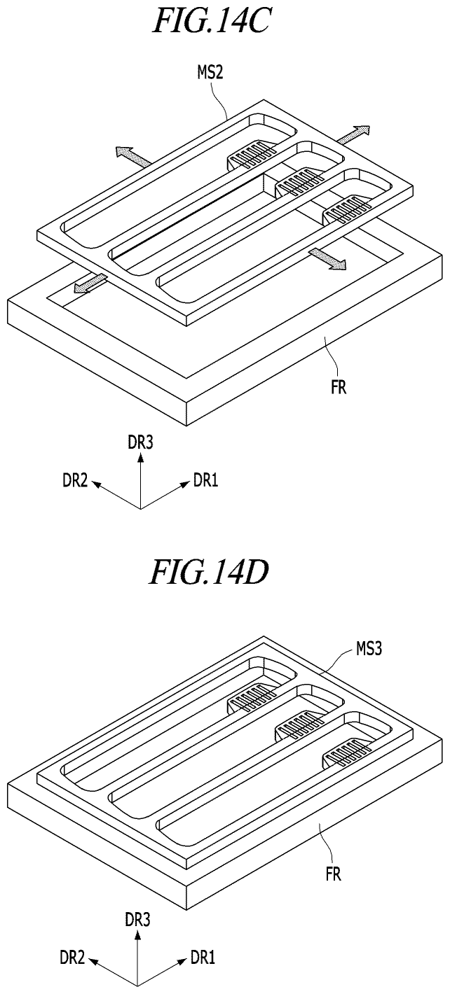

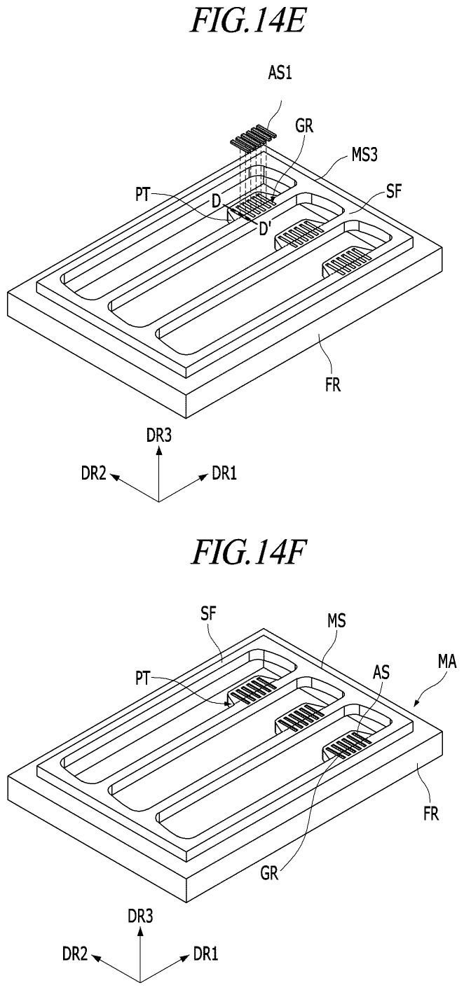

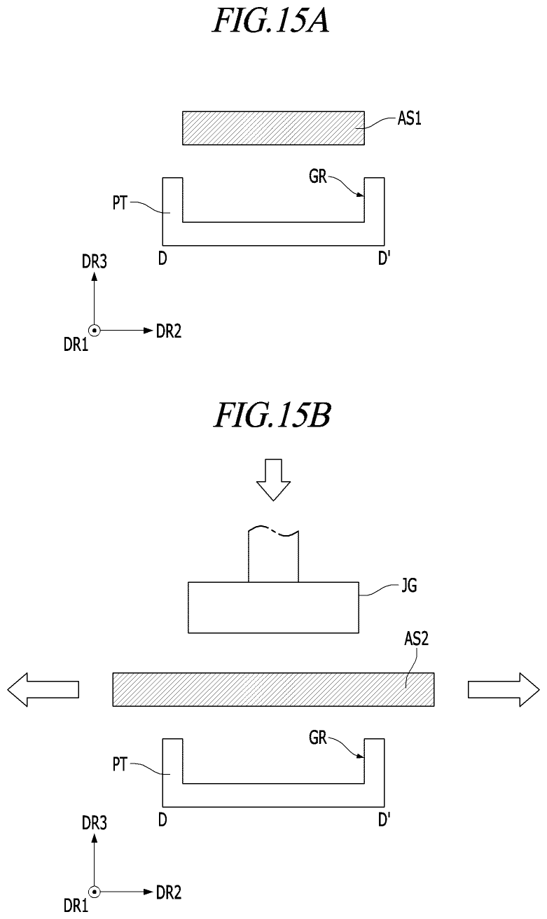

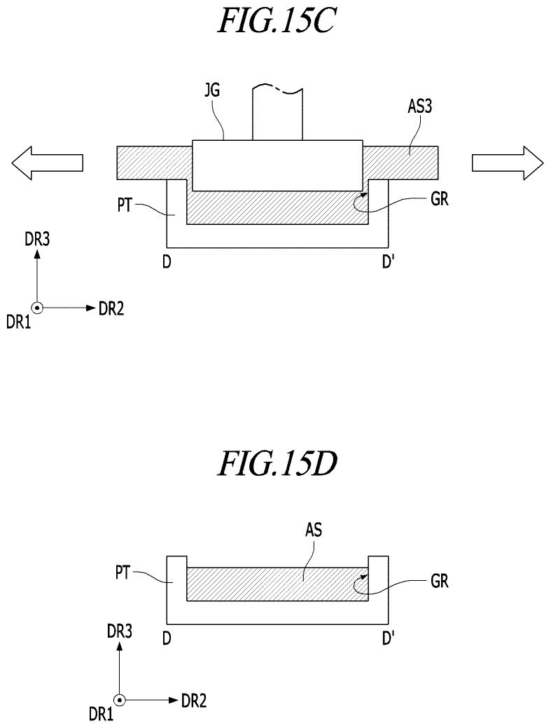

Hereinafter, a method for manufacturing a mask assembly according to an embodiment of the present disclosure will be described with reference to FIGS. 14A to 15C. Any elements described with reference to FIGS. 1 to 13 will be identified with the same reference numerals but will not be redundantly described.

In the descriptions of the method herein, the operations may be performed in a different order than the order shown and/or described, or the operations may be performed in different orders or at different times. Certain operations may also be left out of the method, one or more operations may be repeated, or other operations may be added. Descriptions that an element “may be disposed,” “may be formed,” “may be aligned,” and the like include methods, processes, and techniques for disposing, forming, positioning, and modifying the element, and the like in accordance with example aspects described herein. FIGS. 14A to 14F are perspective views illustrating the method of manufacturing a mask assembly in accordance with an embodiment of the present disclosure. FIGS. 15A to 15D are cross-sectional views illustrating how the auxiliary stick is disposed in accordance with an embodiment of the present disclosure.

Referring to FIGS. 14A to 14F, the method for manufacturing a mask assembly MA may include: preparing a mask sheet; forming openings, protrusions, and stick seating grooves within the mask sheet; mounting the mask sheet onto a frame; and disposing auxiliary sticks in the stick seating grooves.

Referring to FIGS. 14A and 14B, in the step of preparing the mask sheet, the method may include preparing an original mask sheet MS1. In the step of forming openings, protrusions, and stick seating grooves within the mask sheet, the method may include etching the prepared original mask sheet MS1 to form openings OP, protrusions PT, and stick seating grooves GR.

The openings OP may be formed such that the openings OP are surrounded by the protrusions PT and a sheet frame SF connected to the protrusions PT.

The protrusions PT may be formed such that the protrusions PT protrude in the first direction DR1 toward the openings and have the stick seating grooves GR included therein.

Referring to FIGS. 14B to 14D, in the step of mounting the mask sheet onto a frame, the method may include stretching the etched mask sheet MS2 in both directions of the first direction DR1 (e.g., positive first direction DR1 and negative first direction DR1) and in both directions of the second direction DR2 (e.g., positive second direction DR2 and negative second direction DR2) and then mounting the resultant stretched mask sheet MS3 onto the frame. FIG. 14D is illustrated with the frame FR and the stretched mask sheet MS3 mounted on the frame FR.

Referring to FIGS. 14E and 14F, in the step of disposing auxiliary sticks in the stick seating grooves, the method may include: aligning the original stick AS1; stretching the original stick AS1; and welding the stretched original stick AS2 (see FIG. 15B) in the stick seating grooves GR.

Referring to FIGS. 14E and 15A, in the step of aligning the original stick AS1, the method may include aligning the center axis of the original stick AS1 extending in the second direction DR2 and the center axis of the stick seating grooves GR extending in the second direction DR2 with each other in the second direction DR2 (and/or the first direction DR1) on the protrusion PT.

Referring to FIGS. 15A to 15C, in the step of stretching the original stick AS1, the method may include stretching the original stick AS1 in both directions of the second direction DR2. Then, the method may include pushing the stretched original stick AS2 into the stick seating groove GR using a pressing jig JG such that the original stick AS2 is tightly fitted in the stick seating groove GR. FIG. 15C is illustrated with the original stick AS3 tightly fitted within the stick seating groove GR.

In an embodiment of the present disclosure, in the step of welding the stretched original stick AS2 in the stick seating grooves GR, the method may include performing welding from the bottom side of the mask sheet MS. That is, for example, the method may include welding the stretched original stick AS2 to the bottom side of the mask sheet MS. Accordingly, slag (not illustrated), may be formed inside the stick seating groove GR during the welding process.

Referring to FIGS. 15C and 15D, the method of manufacturing the mask assembly in accordance with an embodiment may further include removing a portion of the stick seating groove GR and the stretched original stick on a plane, which may thereby form an auxiliary stick AS. The terms “on a plane” and “in a plan view” may be used interchangeably herein.

The method of manufacturing the mask assembly in accordance with an embodiment of the present disclosure may mitigate the sagging of the protrusions PT by coupling the stretched auxiliary sticks AS to the stick seating grooves GR.

While certain embodiments of the present disclosure have been described herein, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A mask assembly comprising:
a frame;
a mask sheet comprising a sheet frame and a protrusion, wherein the sheet frame is coupled to the frame and the protrusion protrudes from the sheet frame; and
an auxiliary stick coupled to the mask sheet,
wherein:
the sheet frame comprises inner surfaces defining an opening of the sheet frame,
the protrusion protrudes toward the opening in a second direction that intersects a first direction, from one of the inner surfaces of the sheet frame extending in the first direction,
the mask sheet comprises a stick seating groove extending in the second direction from the protrusion to the sheet frame, and
the auxiliary stick is disposed within the stick seating groove.

2. The mask assembly of claim 1, wherein the sheet frame and the protrusion have an integrated shape.

3. The mask assembly of claim 1, wherein:
the auxiliary stick is provided in plurality, and
the plurality of auxiliary sticks are arranged such that the plurality of auxiliary sticks are spaced apart from each other in the second direction.

4. The mask assembly of claim 1, wherein a height of the auxiliary stick in a third direction is smaller than or equal to a depth of the stick seating groove in the third direction, the third direction intersecting the first direction and the second direction.

5. The mask assembly of claim 1, wherein a thickness of the sheet frame and a thickness of the protrusion are equal in a third direction intersecting the first direction and the second direction.

6. The mask assembly of claim 1, wherein a length of the stick seating groove in the second direction is smaller than a length from an end of the protrusion adjacent to the opening in the second direction to an outer surface of the sheet frame facing the end of the protrusion.

7. The mask assembly of claim 1, wherein:
the auxiliary stick overlaps with the protrusion and the sheet frame on a plane, and
a length of the auxiliary stick in the second direction is smaller than or equal to a length of the stick seating groove in the second direction.

8. The mask assembly of claim 7, wherein:
an end of the auxiliary stick facing the opening in the second direction is spaced apart from an end of the protrusion in the second direction, and
another end of the auxiliary stick is spaced apart from an outer surface of the sheet frame facing the end of the protrusion.

9. The mask assembly of claim 1, wherein:
the mask sheet comprises a first surface and a second surface, the first surface being adjacent to a target substrate and the second surface facing opposite to the first surface, and
the stick seating groove is provided on the first surface of the mask sheet.

10. The mask assembly of claim 1, wherein the sheet frame and the auxiliary stick comprise Invar 36.

11. The mask assembly of claim 1, wherein a bottom surface of the auxiliary stick is inclined at a predetermined angle relative to a bottom surface of the stick seating groove.

12. The mask assembly of claim 11, wherein the predetermined angle is 5° or greater.

13. The mask assembly of claim 1, wherein:
the stick seating groove is provided in plurality, and
the auxiliary stick has an H-beam shape extending in the second direction.

14. The mask assembly of claim 1, wherein the protrusion comprises:
a first area overlapping with the auxiliary stick on a plane perpendicular to the second direction and having a width equal to a width of the auxiliary stick in the first direction; and
a second area not overlapping with the first area, wherein the second area has a width equal to the width of the first area on the plane and has an area equal to the first area,
wherein a second moment of area of the first area relative to the first direction is greater than or equal to a second moment of area of the second area relative to the first direction.

15. A method of manufacturing a mask assembly, the method comprising:
providing a mask sheet comprising a sheet frame and a protrusion, wherein the sheet frame comprises inner surfaces defining an opening of the sheet frame, and the protrusion protrudes toward the opening in a second direction that intersects a first direction, from one of the inner surfaces of the sheet frame extending in the first direction;
forming a stick seating groove on the mask sheet, the stick seating groove extending in the second direction from the protrusion to the sheet frame; and
disposing an auxiliary stick within the stick seating groove.

16. The method of claim 15, wherein disposing the auxiliary stick comprises:
aligning, on the protrusion, a center axis of an original stick extending in the second direction with a center axis of the stick seating groove extending in the second direction;
stretching the original stick in the second direction; and
welding the stretched original stick to the stick seating groove.

17. The method of claim 16, wherein:
forming the stick seating groove comprises forming the stick seating groove on a first surface of the mask sheet, and
Welding the stretched original stick is performed upward from a second surface to the first surface, and
the second surface faces opposite to the first surface of the mask sheet where the stick seating groove is formed.

18. The method of claim 17, further comprising removing a portion of the stretched original stick that does not overlap with the stick seating groove on a plane.

19. A mask assembly comprising:
a frame;
a mask sheet coupled to the frame; and
an auxiliary stick coupled to the mask sheet,
wherein:
the mask sheet comprises:
a first rib extending in a first direction;
a second rib extending in the first direction and spaced apart from the first rib in the first direction;
a connecting portion connected to the first rib and the second rib; and
a protrusion connected between the first rib and the second rib in the first direction and protruding in a second direction intersecting the first direction relative to the first rib and the second rib, wherein the protrusion comprises a stick seating groove extending in the first direction, and
the auxiliary stick is disposed within the stick seating groove.

20. The mask assembly of claim 19, wherein:
the first rib, the second rib, the connecting portion and the protrusion have an integrated shape, and
respective thicknesses of the first rib, the second rib, the connecting portion, and the protrusion are equal to one another.
